(19) United States
(12) Patent Application Publication
(10) Pub. No.: US 2012/0189887 A1
(43) Pub. Date: Jul. 26, 2012

(54) ELECTRICAL ENERGY STORAGE DEVICE MADE OF FLAT CELLS AND FRAME ELEMENTS WITH A SUPPLY CHANNEL

(75) Inventors: Claus-Rupert Hohenthanner, Hanau (DE); Torsten Schmidt, Landsberg (DE); Jens Meintschel, Bernsdorf (DE); Andreas Fuchs, Leipzig (DE)

(73) Assignee: Li-Tec Battery GmbH, Kamenz (DE)

(21) Appl. No.: 13/381,428

(22) PCT Filed: Jun. 7, 2010
(86) PCT No.: PCT/EP2010/003409

§ 371 Date: Apr. 3, 2012

(30) Foreign Application Priority Data
Jun. 30, 2009 (DE) 10 2009 031 127.0

(51) Int. Cl. H01M 10/48; H01M 2/14; H01M 6/50; H05K 7/02

(52) U.S. Cl. 429/90; 361/811; 429/247

(57) ABSTRACT

The invention relates to an electrical energy storage device comprising a plurality of flat storage cells for storing and discharging electrical energy, having opposing flat current collectors, a plurality of frame elements for maintaining the storage cells, and a clamping means for clamping the cells with the frame elements into a stack. Each storage cell carries at least one measurement or sensor element for measuring at least one physical variable, to which at least one respective cable for transmitting the measurement data is fixed. The frame elements comprise first recesses for receiving the measurement or sensor elements and second recesses connected to the first recesses, the second recesses of the frame elements together forming at least one channel extending over the length of the device for receiving the cables.

The present invention relates to an electric energy storage device comprising flat cells and frame elements, and a frame element for use in such an electric energy storage device.

It is known to construct electric energy storage cells in the form of storage elements that are flat and rectangular in design. Such electric energy storage cells are so-called pouch or coffee bag cells, for example, in other words, flat and rectangular-shaped cells for storing electric energy (battery cells, accumulator cells, capacitors, . . . ), more particularly, galvanic cells, the electrochemically active part of which is encompassed by a film-type casing, through which electrical connections (terminals) in laminar form, or (current) arresters, are guided. It is further known to construct an electric energy storage device from a plurality of such electric energy storage cells, which are combined by means of a clamping device to form a block. The cells are electrically connected in series or in parallel by means of conductive contact elements, which produce the electric connection between the corresponding current arresters of adjacent cells. In this connection, it is common to arrange the cells, which are loosely held within a frame or pressed together by means of a clamp or the like, in a stack (also called a “cell block”), and to connect the terminals, which are exposed at the top on a narrow side of the cells, by suitable means. In addition to the connecting means for connecting the cells, cables are also installed from the cells to the battery electronics, for the purpose of measuring cell voltage for balancing (charge equalization) or for measuring temperature. As a result of this, costs are increased, structural space is required, and the weight is increased.

One problem addressed by the present invention is that of improving the structure of an electric energy storage device particularly (but not exclusively) in terms of the above-described aspects.

This problem is solved by the features of the independent claims. Advantageous further developments of the invention form the subject matter of the dependent claims.

An electric energy storage device according to the invention comprises: a plurality of flat storage cells for storing and delivering electric energy, with opposite, flat current arresters, a plurality of frame elements for holding the storage cells, and a clamping means for clamping the cells with the frame elements to form a stack, wherein each storage cell supports at least one measuring or sensing element for measuring at least one physical variable, more particularly, the temperature and/or the voltage, wherein a cable for transmitting measurement data is attached to each measuring or sensing element, wherein the frame elements have first recesses for accommodating the measurement or sensing elements and second recesses, which are connected to the first recesses, wherein the second recesses in the frame elements together form at least one channel extending over the length of the device for accommodating the cables.

Within the context of the invention, an electric energy storage device is understood as a device, which is also designed and equipped for delivering electric energy, wherein the energy can be stored in one or more storage cells. The storage cells themselves are naturally also designed and equipped for delivering electric energy. A storage cell within the context of the present invention is any type of apparatus for the electrical storage of energy. The term therefore comprises particularly electrochemical or galvanic cells of the primary type (so-called batteries, which are able to deliver the chemical energy that has been stored in them once via electrochemical energy, and are then used up), or of the secondary type (so-called accumulators, which can be recharged by supplying them with electric charges, in other words electric energy, via an electrochemical reaction), but also other types of energy storage devices, such as capacitors, for example. Storage cells within the context of the invention can particularly have an active part, within which charging and, if applicable, processes for converting electric energy take place, and which is encompassed by a film-type casing, for example, preferably gas-tight and liquid-tight. In this case, so-called current arresters project outward from the interior of the active part, with which they are conductively connected, through the casing to the exterior of the cell, making it possible to connect the active parts of the cells to one another or to a consumer.

Within the context of the invention, flat is understood as a geometric shape that has a smaller extension in one spatial direction than in two other spatial directions. A frame element within the context of the invention is understood, for example, as a substantially prismatic spatial form, preferably flat in the extrusion direction, which has a lower material thickness in the radially inner region than in the radially outer region, wherein particularly prismatic, hollow spatial forms are also covered by this, i.e., spatial shapes that have no material inside a radially inner region. The material thickness can, but need not necessarily, be substantially constant in the radially outer region (the frame in the actual sense).

Within the context of the invention, a measuring or sensing element is understood as any type of apparatus that is designed and configured for passively or actively detecting a physical variable; this apparatus can be limited to merely a line end that is connected or exposed to a measuring environment, or can be equipped with an electrical system and/or electronic system for processing measurement data. The measuring or sensing element can also be designed and equipped for emitting signals and/or charges in the direction of the measuring environment, for example, at a current arrester; more particularly, it can also function as an actuating element. The measuring or sensing element can comprise means for fastening it to or in the measuring environment.

Within the context of the invention, a cable is understood as any apparatus for conducting currents and/or signals; a cable can involve, for example, electrical or optical or other types of conductors; combinations of multiple conductors of different types are also covered by the term.

Within the context of the invention, a recess is understood as any kind of removal of material from a geometric basic shape; this can involve, for example, notches, cavities, pockets, depressions, or other cavities, blind holes or through holes, or grooves, or the like. Within the context of the invention, a channel is understood as a continuous recess extending over the length of the entire device, via which a cable can be guided. Within the context of the invention, the length of the device is understood as essentially the length that is determined by the frame elements stacked one on top of the other; however, the channel can extend further through components that are disposed on the end surface of the stack of frame elements, for example; the channel can also end before a last frame element, as long as measuring or sensing elements can still be accessed there.

Because at least one measuring or sensing element is attached to each storage cell for the purpose of measuring a physical variable, more particularly, temperature, it is also possible to establish a precise characteristic profile, more particularly, a temperature profile, for the storage cells, which enables, for example, a precise and selective regulation particularly of the temperature balance of the cell stack, for example, by localized cooling. If the measurement extends to voltage, for example, a suitable regulation of the charge equalization between the individual cells of the cell stack is possible. Because the frame elements comprise first recesses for accommodating the measuring and/or sensing elements, the measuring and/or sensing elements can also be housed in a space-saving manner. The data cables can be guided inconspicuously and protected through the channel formed by the second recesses, for example, making use of a dead space, and also remain weight neutral due to the removal of material from the frame elements. Because the current arresters of the storage cells are disposed opposite one another, the storage cells can be reliably connected in series and/or in parallel in a simple manner. Because the cells are clamped together with the frame elements to form a stack, a number of flat storage cells can also be arranged in a space-saving and installation-friendly manner to form a stable block.

The device can be embodied such that the second recesses are open toward the radially outer edge of the frame elements. This leaves the channel open for easy access for the purpose of installing cable, maintenance and configuration.

If a sealing device, such as a bracket, for example, is provided for sealing off the at least one channel, the data cables can be guided inconspicuously and protected in the case of a channel that is opened toward the outside.

For attaching the measuring and/or sensing elements, at least one current arrester for each of the storage cells is provided. There, for example, electric variables such as cell voltage can be directly read off, and other physical variables such as temperature can be readily transported out of the interior of the cell and read off via the current arresters. An attachment in the present context is understood as a positioning that prevents any displacement in a radial or axial direction, at least when the stack is clamped; attachment can be achieved by clamping, gluing, riveting, soldering, etc., in other words, particularly separably or inseparably.

If the current arresters of the cells are each clamped by the clamping means by way of a force closure between frame elements, a predefined distance between adjacent cells can also be maintained, which can be adjusted such that no clamping force is exerted on an electrochemically active part of the cells. This can also have advantages with respect to the functional reliability and the service life of the cells; moreover, the flat sides of the cells can radiate heat to a heat transfer medium, or, if applicable, can absorb heat therefrom, for example, during start-up at low temperatures. Using suitable means, such as a separate conductance of a cooling medium or the like, the temperature can be individually controlled in any intermediate space between adjoining cells. The clamping of the storage cells between the frame elements on the current arresters is facilitated by the opposite arrangement of the current arresters; a reliable fastening of the storage cells, fixed in place and in position, in the block is thereby also facilitated.

If compression end pieces, which are clamped with the stack on the end surface frame elements via the clamping elements, have a through opening at the level of each channel, the cables can be guided out of the stack in a particularly simple manner. Within the context of the invention, a compression end piece is understood as a component that is designed and configured to accept clamping forces exerted by the clamping means, and, for example, to transfer said forces as compressive forces via the end surface frame elements into the stack. In this, it is advantageous for the compression end pieces to introduce the potentially locally occurring clamping forces of the clamping means, distributed uniformly, into the frame elements as compressive forces.

Due to the sensitive temperature balance, the invention is particularly advantageous for Li-ion accumulators. Within the context of the invention, a Li-ion accumulator is understood as an electric energy storage device, which comprises galvanic cells, particularly secondary cells, in which an internal voltage is generated by the displacement of lithium ions between a positive and a negative electrode. With flat lithium-ion accumulator cells, the positive electrode, the negative electrode and an electrolyte can be provided, for example, in layers in a film stack, wherein the layer sequence or parts thereof can repeat once or multiple times, and wherein the layers (films) of the positive electrodes are connected to a first current arrester, and the layers (films) of the negative electrodes are connected to a second current arrester, and the electrolyte films serve as barrier layers.

The invention also relates to a frame element, which is configured for use in an electric energy storage device as described above.

The preceding and additional features and advantages of, and problems addressed by the present invention will be described in greater detail in what follows, in which reference is made to the attached set of drawings.

The drawings show:

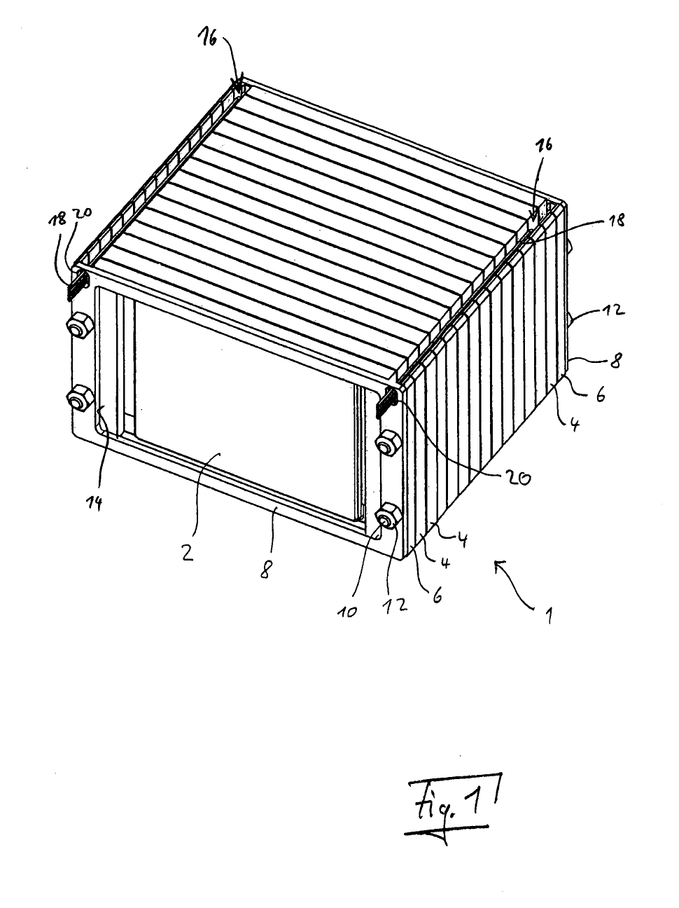

FIG. 1 a perspective illustration of a cell block as one embodiment example of the present invention;

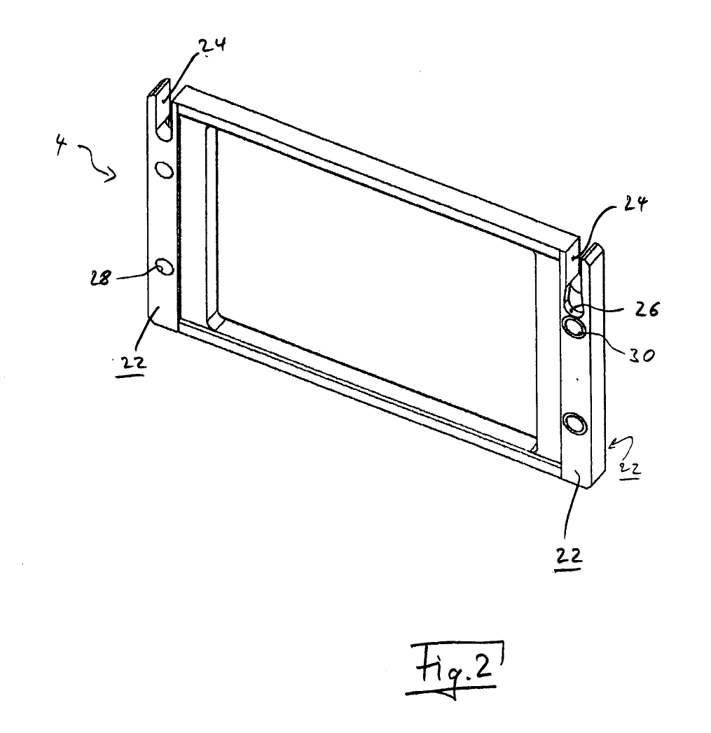

FIG. 2 a perspective illustration of a frame element of the cell block of FIG. 1;

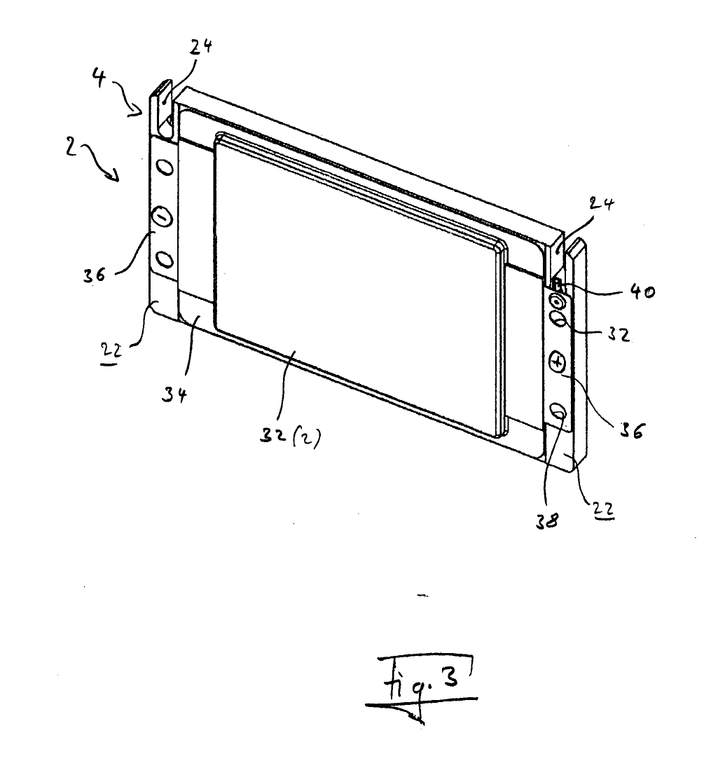

FIG. 3 an illustration of the frame element of FIG. 2, together with a storage cell;

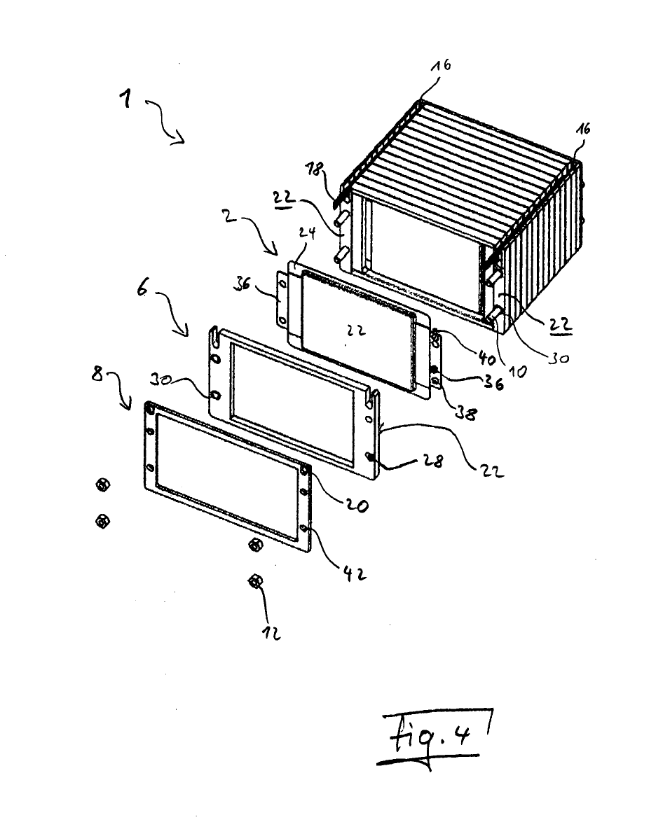

FIG. 4 a perspective, exploded illustration of the cell configuration of FIG. 1;

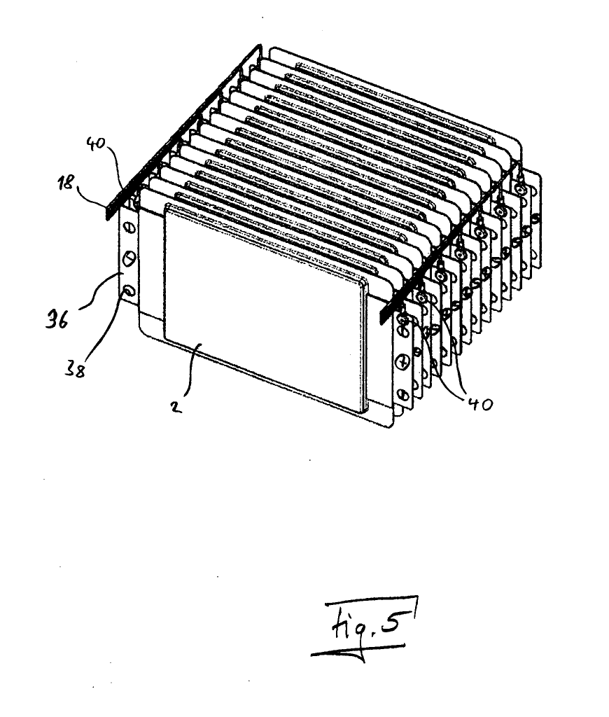

FIG. 5 an illustration of the cell configuration with measuring and/or sensing elements and supply lines to the cell block of FIG. 1, without frame and clamping elements; and

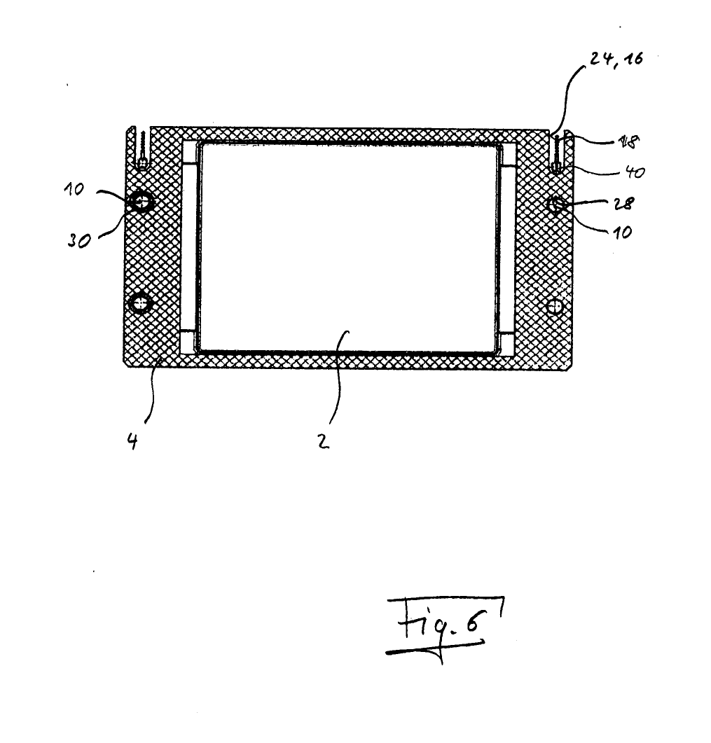

FIG. 6 an end surface view of the cell block of FIG. 1, cut in a plane between two adjacent storage cells.

It should be pointed out that the drawings in the figures are schematic, and are limited to illustrating those features that are most important for an understanding of the invention. It should also be pointed out that the dimensions and size ratios provided in the drawings are intended merely to clarify the illustrations and are in no way intended as restrictive.

In what follows, one embodiment example of the present invention will be described in reference to FIGS. 1 to 6.

FIG. 1 is a perspective illustration of a cell block as one embodiment example of the present invention.

According to the perspective overall illustration of FIG. 1, a cell block 1 comprises a plurality of storage cells 2 (galvanic cells, accumulator cells, etc., only one of which is visible in FIG. 1), a plurality of intermediate frames 4, two end frames 6, two compression panels 8, and four tie bolts 10 with nuts 12 positioned on both ends thereof. One of the two end frames 4, the intermediate frames 6 and the second of the two end frames 4, in this sequence, form a block, which is held together across the compression panels 8 disposed at the ends, by means of the tie bolts 10 and the nuts 12. The compression panels 8 have a window opening 14 and are therefore embodied as frame-shaped. The storage cells 2 are located within the structure formed by the stacked frames 4, 6, as will be described in greater detail in what follows.

Reference is made first to two supply channels 16, formed on the left and right sides of the upper side of the block formed by the intermediate and end frames 4, 6. Low-voltage cables 18 extend in the supply channels 16, and are guided through openings 20 in the front compression panel 8.

FIG. 2 illustrates one of the intermediate frames 4 of the block of FIG. 1 separately.

The intermediate frame 4 has a square-shaped contour, with two flat sides, and four narrow sides forming a continuous frame. The surface normal of the flat sides corresponds to the stacking direction of the frames in the cell block of FIG. 1. At the center, a window-like opening is formed, so that the remaining legs form a frame. On the lateral, vertical legs of the intermediate frame, compression surfaces 22 are formed at the front and the back.

Extending outward from the upper narrow side, on the left and the right, one notch 24 extends downward into each vertical leg. In the extension of each notch 24, a pocket-shaped depression 26 is formed in each of the compression surfaces. It should be pointed out that in the right vertical leg, the depression is formed on the front side, whereas in the left vertical leg, the depression is formed on the back side.

In one of the vertical legs, two through holes 28 are formed, which connect the compression surfaces 22 in the stacking direction. In each of two other through holes, not specified in greater detail, in the other of the vertical legs, which through holes have a larger diameter than through holes 28, sleeves 30 are inserted. The sleeves 30 are produced from a highly electrically conductive material, and are used for through contacting between the compression surfaces 22 of this leg.

The above statements relating to the intermediate frames 4 apply similarly to the end frames 6, in which, however, a depression 26 is formed only on the side facing the cells.

FIG. 3 shows the intermediate frame 4 of FIG. 2 together with a storage cell 2.

According to the illustration in FIG. 3, the storage cells 2 are configured as so-called flat cells or pouch cells, with opposite, flat current arresters. More precisely, each storage cell 2 comprises an active part 32, a sealing joint (an edge region) 34 and two current arresters 36. The electrochemical reactions for storing and discharging electric energy take place in the active part 32. In principle, any type of electrochemical reaction can be used for constructing storage cells; however, the description relates particularly to Li-ion accumulators, to which the invention is particularly applicable due to the requirements relating to mechanical stability and heat balance, and due to its economic significance. The active part 32 is encompassed by two films (not illustrated in greater detail) in a sandwich construction, wherein the overhanging edges of the films are welded to one another gas-tight and liquid-tight, and form the so-called sealing joint 34. The current arresters 36 project outward from two opposite narrow sides of the storage cell 2 as a positive terminal (+) and a negative terminal (−).

The current arresters 36 each comprise two through holes 38 (hereinafter referred to as “terminal holes”), which are aligned with the through holes 28 and the sleeves 30 in the intermediate frame 4. The diameter of the terminal holes 38 is equal to the diameter of the through holes 28 and the inner diameter of the sleeves 30.

On the back of the right current arrester 36, a sensing element 40 is attached, the body of which is held inside the depression 26 of the intermediate frame 4. The sensing element 40 is configured for emitting an output signal at the connection end thereof, on the basis of the temperature and the voltage at the current arrester 36. The sensing element 40 is preferably configured for receiving the voltage and/or a signal on the basis of additional physical variables such as temperature, etc. The sensing element is further configured for receiving a low-voltage current via its connection end, and for delivering said current to the arrester 36, or vice versa. Via a control device, not illustrated here, an electric charge can thereby be supplied to the cell 2 or received therefrom, and therefore, charge equalization can be carried out between the cells 2 within the cell block 1. Additionally, the output signal of the sensing element 40 can be evaluated in the control device, and, for example, locally individualized temperature compensation can be implemented via suitable heating technology means.

FIG. 4 shows the cell block 1 of FIG. 1 in a perspective, partially exploded view. In other words, the nuts 12 have been removed, and on the side that faces the observer, the compression panels 8, the end frames 4, a storage cell 2 and an intermediate frame 6 have been removed from the tie bolts 10.

The drawing clearly illustrates the way in which the storage cells 2 are held in a sandwich construction between the compression surfaces 22 of the frames 4, 6, and are clamped together via the tie bolts 10. The tie bolts 10 extend through the through holes 28, the sleeves 30, the terminal holes 38 and the eyes 42, which are formed in the compression panel 8, all of which are aligned with one another. When the nuts 12 are tightened onto the tie bolts 10, the entire cell block 1 is clamped such that the storage cells 2 are held securely between the frames 4, 6 and/or 4, 4.

Thus the frames 4, 6 are arranged in the stack in such a way that the sleeves 30 come to rest on alternating lateral sides of the stack. According to the illustration of FIG. 5, in which the arrangement of the cells in the cell stack 1 is illustrated along with sensing elements 40 and supply lines 18, but without frames 4, 6 and clamping elements 10, 12, the storage cells 2 are further arranged in the stacking direction with the current arresters 36 in alternating terminal positions. In other words, in adjacent storage cells 36, current arresters 36 of opposite polarity always lie opposite one another. The sleeves 30, in turn, are pressed in the stack against the opposite current arresters 36 by means of the clamping elements 10, 12, thereby producing an electrically conductive connection between said current arresters. In this manner, the current arresters 36 of opposite polarity are continuously connected to one another in the stack, and a series connection of the storage cells 2 is produced.

Each of sleeves 30 in the end frames 6 connects a current arrester 36 of the first or the last cell 2 to the first or last compression panel 8. The compression panels 8 are made of a conductive material, and therefore represent the terminals of the cell block 1.

The tie bolt 10 is electrically insulated by suitable means, such as a coating or a continuous sleeve made of an insulating material, against the conductive parts or parts having potential, in other words, the current arresters 36, the compression panels 8, and the contact sleeves 30, thereby effectively preventing a short circuit. In addition, spacing can be provided between the tie bolt 10 and the components through which it extends. Although this is not illustrated in the figure, the frames 4, 6, the compression panels 8 and the storage cells 2 are thus held in a radially defined position; suitable centering means include alignment pins or a geometrically suitable shaping of the stacked components. Also not illustrated in the figures is a suitable insulation provided for the nuts 12 in relation to the compression panel 8; this can be implemented, for example, by insulating disks or collar bushings, the cylindrical sections of which extend into the eyes 42 of the respective compression panels 8.

Returning to FIG. 5, this drawing shows that the sensing elements 40, which are each attached to the positive current arresters 36 (+) of the storage cells 2, are arranged on alternating lateral sides in the stacking direction. Thus two strands of supply lines or low-voltage cables 18, each of which is connected to the connecting end of the sensing element 40, extend through the supply channels 16 formed by the interconnection of the notches 24 in the frames 4, 6 (cf., FIGS. 1 and 4) and through the openings 20 in the front compression panel 8, toward the outside, to the control device, which is not shown here.

Finally, FIG. 6 shows an end surface view of the cell block of FIG. 1, cross-cut in a plane between two adjacent storage cells. Here, the position of the sensing elements 40 (only the upper connection end is visible) and the supply lines 18 in the supply channels 16 formed by the notches 24 is shown from the end surface of the cell stack.

The above therefore describes at least one embodiment example of an electric energy storage device, which comprises, according to the invention: a plurality of flat storage cells for storing and delivering electric energy, with opposite, flat current arresters, a plurality of frame elements for holding the storage cells, and a clamping means for clamping the cells with the frame elements to form a stack, wherein each storage cell supports at least one measuring or sensing element for measuring at least one physical variable, more particularly, temperature and/or voltage, wherein a cable for transmitting measurement data is attached to each measuring or sensing element, wherein the frame elements have first recesses for accommodating the measuring and/or sensing elements and second recesses, which are connected to the first recesses, wherein the second recesses of the frame elements together form at least one channel, extending over the length of the device, for accommodating the cables.

The cell block 1 is an electric energy storage device within the context of the invention. The end frames 4 and intermediate frames 6 are examples of frame elements within the context of the invention. The tie bolts 10 and nuts 12 are examples of a clamping means within the context of the invention. The compression panels 8 are examples of compression end pieces within the context of the invention. The sensing element 40 is an example of a measuring or sensing element within the context of the invention. The depression 26 is an example of a first recess within the context of the invention, and the notch 24 is an example of a second recess within the context of the invention. A supply channel 16 is an example of a channel within the context of the invention. The opening 20 is an example of a through opening within the context of the invention. The low-voltage cables 18 are examples of a cable within the context of the invention.

Although the essential features of the present invention have been described above in reference to concrete embodiment examples, it is understood that the invention is not limited to these embodiment examples, and can instead be modified and expanded within the scope and range specified by the patent claims.

The series connection of the storage cells 2 illustrated in the drawings is particularly important in practical usage. However, with a corresponding arrangement of the cells 2 and the contact sleeves 30 in the intermediate frames 4, a parallel connection or combinations of parallel and series connections are also possible.

A centering device for radially centering the cells 2 within a cell block or relative to the spacing elements can be provided. A centering device of this type can be implemented, for example, as alignment pins and alignment holes in the spacing elements and arresters, or through other means.

In a modification, for the purpose of improving measurement and control, measuring and/or sensing elements 40 are attached to each current arrester 38. Attaching the measuring and/or sensing elements 40 to the current arresters 38 is one practical option. However, said elements can be attached at any location on the cell, as long as this offers structural or functional advantages.

In a further modification, each of the measuring and/or sensing elements is formed as a rivet, with which the measuring cable is fastened via cable end shoes.

In a further modification, more than two tie bolts are used on each side.

In a final modification, in place of tie bolts, a clamping belt is used for clamping the cell block.

### LIST OF REFERENCE SIGNS

1 Cell block

2 Storage cell

4 Intermediate frame

6 End frame

8 Compression panel

10 Tie bolt

12 Nut

14 Window in 8

16 Supply channel

18 Low voltage cable

20 Opening in 8

22 Compression surface

24 Notch

26 Depression

28 Through hole in 22

30 Contact sleeve

32 Active part of 2

34 Sealing joint of 2

36 Current arrester of 2 ((+) and (−))

38 Terminal hole in 14

40 Sensing or measuring element

42 Eye in 8

It is expressly pointed out that the above list of reference signs is an integral component of the description.

1-16. (canceled)

17. An electric energy storage device, comprising:
a plurality of flat storage cells to store and deliver electric energy with opposite, flat current arresters,
a plurality of frame elements to hold the storage cells,
and
a clamping means for clamping the cells with the frame elements to form a stack,
wherein each storage cell supports at least one measuring or sensing element to measure at least one physical variable,
wherein a cable to transmit measurement data is attached to each measuring or sensing element,
wherein the frame elements comprise first recesses to accommodate the measuring and/or sensing elements and second recesses, which are connected to the first recesses,
wherein the second recesses of the frame elements together form at least one channel, extending over the length of the device, to accommodate the cables,
wherein the second recesses are open toward the radially outer edge of the frame elements, and a sealing device for sealing off the at least one channel.

18. The electric energy storage device according to claim 17, wherein the sealing device comprises a bracket.

19. The electric energy storage device according to claim 17, wherein the storage cells are arranged with alternating terminal positions in the stack.

20. The electric energy storage device according to claim 19, wherein each of the at least one measuring and/or sensing elements is attached to at least one of the current arresters of the storage cells.

21. The electric energy storage device according to claim 17, wherein the current arresters of each of the cells are clamped by the clamping means by way of a force closure between frame elements.

22. The electric energy storage device according to claim 21, wherein the clamping means comprise a plurality of tie bolts, which extend through holes in the current arresters and the frame elements.

23. The electric energy storage device according to claim 22, wherein the tie bolts are encased in an electrically insulating material or are held inside a continuous insulating sleeve.

24. The electric energy storage device according to claim 21, wherein the frame elements are made of an electrically insulating material including a glass material, a ceramic material or a plastic material, and have contacting elements made of an electrically conductive material, which produce an electrical contact between opposite compression surfaces.

25. The electric energy storage device according to claim 24, wherein the contacting elements are sleeves, through which the tie bolts extend.

26. The electric energy storage device according to claim 17, wherein the stack is bordered by two conductive compression end pieces, which are clamped to the stack on the end-surface frame elements via the clamping means.

27. The electric energy storage device according to claim 26, wherein the compression end pieces are electrically connected to a current arrester of a first or a last cell.

28. The electric energy storage device according to claim 26, wherein the compression end pieces have a through opening at the height of each channel.

29. The electric energy storage device according to claim 17, wherein the storage cells are accumulators, in which an electrochemical reaction takes place.

30. A frame element configured to hold storage cells in an electric energy storage device according to claim 17.

31. The electric energy storage device according to claim 17, wherein the at least one physical variable measured by the at least one measuring or sensing element is temperature or voltage.

32. The electric energy storage device according to claim 20, wherein each of the at least one measuring and/or sensing elements is attached to current arresters having a same polarity.

33. The electric energy storage device according to claim 22, wherein the plurality of tie bolts includes four or six bolts.

34. The electric energy storage device according to claim 26, wherein the two conductive compression end pieces are frame-shaped.

35. The electric energy storage device according to claim 29, wherein the electrochemical reaction involves Li ions.
